(19) United States
(12) Patent Application Publication
(10) Pub. No.: US 2024/0263341 A1
(43) Pub. Date: Aug. 8, 2024

(54) Equipment for Manufacturing Nitrogen-Doped Monocrystalline Silicon and Method for Manufacturing the Same

(71) Applicant: XI’AN ESWIN MATERIAL TECHNOLOGY CO., LTD., Xi'an (CN)

(72) Inventors: Peng HENG, Xi'an (CN); Peng XU, Xi'an (CN); Wanwan ZHANG, Xi'an (CN)

(21) Appl. No.: 18/567,306

(22) PCT Filed: Sep. 29, 2022
(86) PCT No.: PCT/CN2022/122595

§ 371 Date: Dec. 5, 2023

(30) Foreign Application Priority Data
Sep. 30, 2021 (CN) 202111162445.6

(51) Int. Cl. C30B 15/04; C30B 15/10; C30B 15/14; C30B 29/06

(52) U.S. Cl. CPC C30B 15/04; C30B 15/10; C30B 15/14; C30B 29/06

(57) ABSTRACT

An equipment is for manufacturing nitrogen-doped monocrystalline silicon. The equipment includes a quartz crucible, the quartz crucible being used for accommodating a nitrogen-doped silicon melt; a first gas-conveying apparatus, the first gas-conveying apparatus being used for conveying a carbon monoxide gas onto a liquid surface of the nitrogen-doped silicon melt; and a crystal pulling apparatus, the crystal pulling apparatus being used for pulling a monocrystalline silicon ingot with the nitrogen-doped silicon melt by a Czochralski method.

### CROSS-REFERENCE TO RELATED APPLICATION

The present application claims priority to the Chinese patent application No. 202111162445.6 filed in China on Sep. 30, 2021, a disclosure of which is incorporated herein by reference in its entirety.

### FIELD

The present disclosure relates to the field of semiconductor wafer manufacturing, in particular to an equipment for manufacturing nitrogen-doped monocrystalline silicon and a method for manufacturing the same.

### BACKGROUND

Silicon wafers used in the production of semiconductor electronic components such as integrated circuits are mainly produced by slicing monocrystalline silicon ingots pulled by a Czochralski method. The Czochralski method includes melting polysilicon in a quartz crucible to obtain a silicon melt, immersing a single crystal seed into the silicon melt, and continuously pulling the seed to move away from a surface of the silicon melt, whereby a single crystal silicon ingot is grown at the phases interface during the pulling.

In the above production process for the production of semiconductor electronic components, it is very advantageous to provide a silicon wafer with a Denuded Zone (DZ) that extends from the front surface into the body, and a zone including a bulk micro defect (BMD) adjacent to the DZ and further extending into the body, wherein the front surface refers to a surface of the silicon wafer on which electronic components are to be formed. The above-mentioned DZ is important, because in order to form electronic components on the silicon wafer, it is required that there is no crystal defect in the formation area of the electronic components, otherwise it will lead to faults such as circuit open, so that the electronic components can be formed in DZ to avoid the influence of crystal defects. And the function of the above-mentioned BMD is to produce an intrinsic getter (IG) effect on metal impurities, so that the metal impurities in the silicon wafer can be kept away from DZ, so as to avoid adverse effects such as an increase of leakage current and a reduction of gate oxide film quality caused by metal impurities.

In the process of producing the above-mentioned silicon wafers with BMD zones, it is very advantageous to dope with nitrogen in the silicon wafers. For example, in the case of silicon wafers doped with nitrogen, it can promote the formation of BMD with nitrogen as the core, so that the density of BMD can reach a certain level to effectively play a role as a source for absorbing metal impurity, and can also have a beneficial effect on the distribution of the density of BMD, such as the distribution of the density of BMD is more uniformly in the radial direction of the silicon wafer, and the density of BMD higher in the region near DZ and the density of BMD to gradually decrease towards the body of the silicon wafer.

As an example to dope the silicon wafer with nitrogen, the silicon melt in the quartz crucible can be doped with nitrogen, and the monocrystalline silicon ingot pulled therefrom and the silicon wafer cut from the monocrystalline silicon ingot will be doped with nitrogen.

The problem in the process of pulling nitrogen-doped silicon ingots with nitrogen-doped silicon melt is that the nitrogen in the doped silicon melt will volatilize from the silicon melt in the form of nitrogen gas, and cannot enter the silicon ingot during the monocrystalline silicon ingot is grown, resulting in nitrogen unnecessary losses, which leads to the reduction of nitrogen concentration in the entire silicon ingot, so that the above-mentioned beneficial effects due to nitrogen doping unable to be achieved in an effective way.

### SUMMARY

In order to solve the above-mentioned technical problems, embodiments of the present disclosure provide an equipment for manufacturing nitrogen-doped monocrystalline silicon and a method for manufacturing the same, so as to effectively avoid the loss of dopant caused by the volatilization of nitrogen.

The technical schemes of the present disclosure are implemented as follows.

In a first aspect, the embodiments of the present disclosure provide an equipment for manufacturing nitrogen-doped monocrystalline silicon, comprising: a quartz crucible, the quartz crucible being used for accommodating a nitrogen-doped silicon melt; a first gas-conveying apparatus, the first gas-conveying apparatus being used for conveying a carbon monoxide gas onto a liquid surface of the nitrogen-doped silicon melt; and a crystal pulling apparatus, the crystal pulling apparatus being used for pulling a monocrystalline silicon ingot with the nitrogen-doped silicon melt by a Czochralski method.

In a second aspect, the embodiments of the present disclosure provide a method for manufacturing nitrogen-doped monocrystalline silicon, comprising: accommodating a nitrogen-doped silicon melt in a quartz crucible; conveying a carbon monoxide gas onto a liquid surface of the nitrogen-doped silicon melt; and pulling a monocrystalline silicon ingot with the nitrogen-doped silicon melt by a Czochralski method.

The embodiments of the present disclosure provide an equipment for manufacturing nitrogen-doped monocrystalline silicon and a method for manufacturing the same. In the case that the nitrogen-doped silicon melt is accommodated in the quartz crucible, since the composition of the quartz crucible is silicon dioxide (SiO₂), the first chemical reaction will occur at the high temperature when the nitrogen-doped silicon melt is in a molten state: Si+SiO₂→2SiO. Here, the silicon monoxide (SiO) generated here exists as a gas at high temperature. And on this basis, when the carbon monoxide gas is conveyed onto the liquid surface of the nitrogen-doped silicon melt, the carbon monoxide gas, the doped nitrogen volatilized in the form of nitrogen gas, and the SiO generated by the first chemical reaction will lead to such a second chemical reaction: 3SiO+2N₂+3CO→Si₃N₄+3CO₂. Here, the carbon dioxide (CO₂) generated here exists as a gas at high temperature. For the generated silicon nitride (Si₃N₄), due to its high melting point, it still exists in a solid state at high temperatures, so it will return to the melt, so that the nitrogen volatilized from the melt will be returned to the melt, resulting in the loss of nitrogen is reduced and improving the situation of the nitrogen concentration decline in the pulled entire monocrystalline silicon ingot.

### BRIEF DESCRIPTION OF THE DRAWINGS

FIG. 1 is a schematic view of an equipment for manufacturing nitrogen-doped monocrystalline silicon according to embodiments of the present disclosure; and

FIG. 2 is a flow chart of a method for manufacturing nitrogen-doped monocrystalline silicon according to embodiments of the present disclosure.

### DETAILED DESCRIPTION

The present disclosure will be described hereinafter in a clear and complete manner in conjunction with the drawings and embodiments.

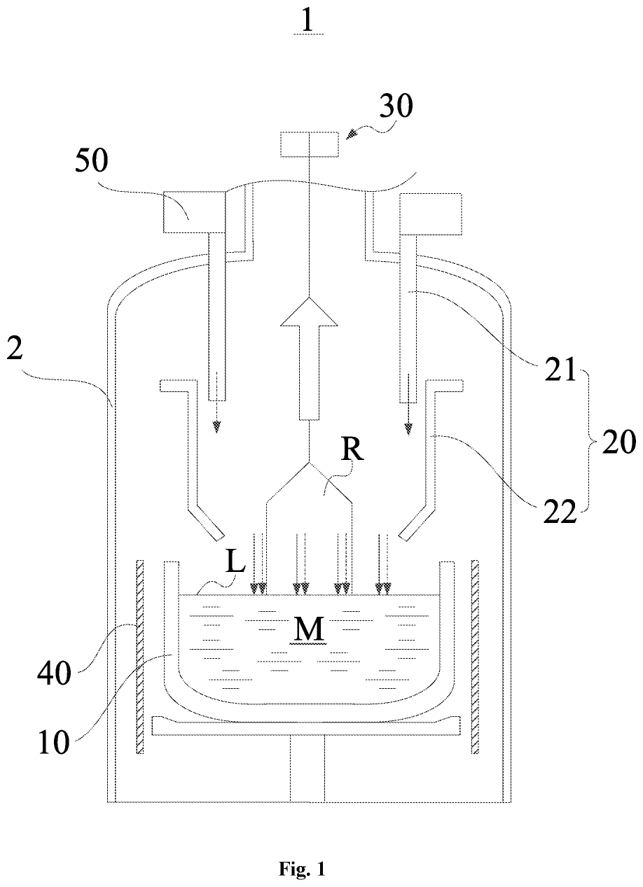

As shown in FIG. 1, the embodiment of the present disclosure provides an equipment 1 for manufacturing nitrogen-doped monocrystalline silicon, the equipment 1 comprising:
a quartz crucible 10, the quartz crucible 10 being used for accommodating a nitrogen-doped silicon melt M;
a first gas-conveying apparatus 20, the first gas-conveying apparatus 20 being used for conveying a carbon monoxide (CO) gas onto a liquid surface L of the nitrogen-doped silicon melt M. Here, FIG. 1 schematically shows a specific implementation of the first gas-conveying apparatus 20 when the quartz crucible 10 and the nitrogen-doped silicon melt M accommodating in the quartz crucible 10 are in the puller body 2. As shown in FIG. 1, the first gas-conveying apparatus 20 conveys carbon monoxide gas to the interior of puller body 2 and conveys the carbon monoxide gas onto the liquid surface L of nitrogen-doped silicon melt M, as schematically shown by a solid arrow; and
a crystal pulling apparatus 30, the crystal pulling apparatus 30 being used for pulling a monocrystalline silicon ingot R by using the nitrogen-doped silicon melt M through a Czochralski method. Here, for the crystal pulling apparatus 30 shown schematically in FIG. 1, the crystal pulling apparatus 30 is located at the top of the puller body 2, and the monocrystalline silicon ingot R is moved along the direction shown by the hollow arrow in FIG. 1, so that the monocrystalline silicon ingot R is grown continuously at the phases interface, that is, at the liquid surface L.

In the case that the nitrogen-doped silicon melt M is accommodated in the quartz crucible 10, since the composition of the quartz crucible 10 is silicon dioxide (SiO₂), the first chemical reaction will occur at the high temperature when the nitrogen-doped silicon melt M is in a molten state: Si+SiO₂→2SiO. Here, the silicon monoxide (SiO) generated here exists as a gas at high temperature. And on this basis, when the carbon monoxide gas is conveyed onto the liquid surface L of the nitrogen-doped silicon melt M, the carbon monoxide gas, the doped nitrogen volatilized in the form of nitrogen gas, and the SiO generated by the first chemical reaction will lead to such a second chemical reaction: 3SiO+2N₂+3CO→Si₃N₄+3CO₂. Here, the carbon dioxide (CO₂) generated here exists as a gas at high temperature. For the generated silicon nitride (Si₃N₄), due to its high melting point, it still exists in a solid state at high temperatures, so it will return to the melt, so that the nitrogen volatilized from the melt will be returned to the melt, resulting in the loss of nitrogen is reduced and improving the situation of the nitrogen concentration decline in the pulled entire monocrystalline silicon ingot.

For the obtainment of the nitrogen-doped silicon melt M, in the equipment 1 according to the embodiments of the present disclosure, as shown in FIG. 1, the equipment 1 can also comprise: a heating apparatus 40, the heating apparatus 40 being used to heat the quartz crucible 10 to melt a silicon nitride and a polycrystalline silicon accommodated in the quartz crucible 10, so as to obtain the nitrogen-doped silicon melt M.

For the implementation of the first gas-conveying apparatus 20, in one example, as shown in FIG. 1, the first gas-conveying apparatus 20 comprises:
a first gas supplier 21, the first gas supplier 21 being used to supply the carbon monoxide gas which is specifically supplied to the interior of puller body 2; and
a reflector 22, the reflector 22 being used to guide the carbon monoxide gas supplied by the first gas supplier 21, specifically which has supplied to the interior of puller body 2, onto the liquid surface L of the nitrogen-doped silicon melt M.

To avoid unexpected chemical reactions between nitrogen-doped silicon melt M at high-temperature and surrounding gases such as oxygen gas in the atmosphere, it is necessary to maintain nitrogen-doped silicon melt M in an atmosphere of protective gas. Therefore, as shown in FIG. 1, the equipment 1 can further comprise a second gas supplier 50, the second gas supplier 50 being used to supply an inert gas. Specifically the inert gas is supplied to the puller body 2 as schematically shown by the dotted arrows in FIG. 1. And the reflector 22 is also used for guiding the inert gas supplied by the second gas supplier 50 onto the liquid surface L of the nitrogen-doped silicon melt M, as shown schematically by the dotted arrows in FIG. 1.

For the above types of inert gases, in one example, the inert gas is an argon gas.

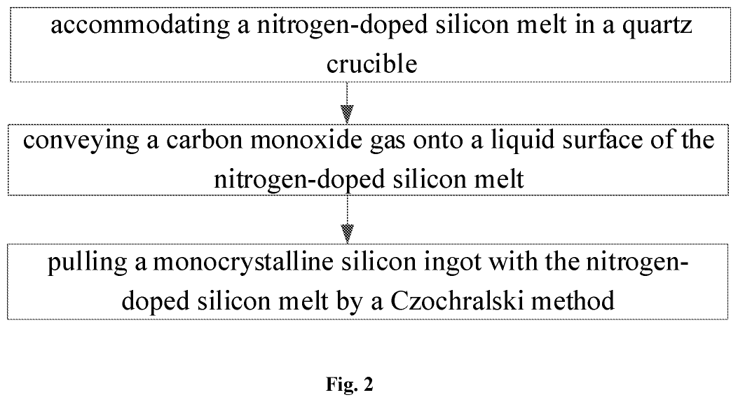

As shown in FIG. 2, the embodiment of the present disclosure also provides a method for manufacturing nitrogen-doped monocrystalline silicon, comprising:
accommodating a nitrogen-doped silicon melt in a quartz crucible;
conveying a carbon monoxide gas onto a liquid surface of the nitrogen-doped silicon melt; and
pulling a monocrystalline silicon ingot with the nitrogen-doped silicon melt by a Czochralski method.

For the obtainment of the nitrogen-doped silicon melt, in the method according to the embodiments of the present disclosure, the method also comprises:
heating the quartz crucible to melt a silicon nitride and a polycrystalline silicon accommodated in the quartz crucible, so as to obtain the nitrogen-doped silicon melt.

In another example, conveying the carbon monoxide gas onto the liquid surface of the nitrogen-doped melt comprises:
supplying the carbon monoxide gas; and
guiding the supplied carbon monoxide gas onto the liquid surface of the nitrogen-doped silicon melt.

As previously described, in order to maintain the nitrogen-doped melt in an atmosphere of protective gas, the method also comprises:
supplying an inert gas; and
guiding the supplied inert gas together with the carbon monoxide gas onto the liquid surface of the nitrogen-doped silicon melt.

The inert gas mentioned in the above methods is an argon gas.

It should be noted that, where not conflicting, the embodiments of the present disclosure and features within the embodiments may be combined with each other to obtain new embodiments.

The above are only specific embodiments of this present disclosure, but the protection scope of the present disclosure is not limited thereto. Within the scope of the art disclosed in this disclosure, a change or replacement can be easily thought by any person skilled in the art should be covered by the scope of protection of this disclosure. Therefore, the protection scope of the present disclosure should be subject to the protection scope of the claims.

1. An equipment for manufacturing nitrogen-doped monocrystalline silicon, comprising:
a quartz crucible, the quartz crucible being used for accommodating a nitrogen-doped silicon melt;
a first gas-conveying apparatus, the first gas-conveying apparatus being used for conveying a carbon monoxide gas onto a liquid surface of the nitrogen-doped silicon melt; and
a crystal pulling apparatus, the crystal pulling apparatus being used for pulling a monocrystalline silicon ingot with the nitrogen-doped silicon melt by a Czochralski method.

2. The equipment according to claim 1, further comprising:
a heating apparatus, the heating apparatus being used to heat the quartz crucible to melt a silicon nitride and a polycrystalline silicon accommodated in the quartz crucible and to obtain the nitrogen-doped silicon melt.

3. The equipment according to claim 1, wherein the first gas-conveying apparatus comprises:
a first gas supplier, the first gas supplier being used to supply the carbon monoxide gas; and
a reflector, the reflector being used to guide the carbon monoxide gas supplied by the first gas supplier onto the liquid surface of the nitrogen-doped silicon melt.

4. The equipment according to claim 3, further comprising:
a second gas supplier, the second gas supplier being used to supply an inert gas,
wherein the reflector is also used to guide the inert gas supplied by the second gas supplier onto the liquid surface of the nitrogen-doped silicon melt.

5. The equipment according to claim 4, wherein the inert gas is an argon gas.

6. A method for manufacturing nitrogen-doped monocrystalline silicon, comprising:
accommodating a nitrogen-doped silicon melt in a quartz crucible;
conveying a carbon monoxide gas onto a liquid surface of the nitrogen-doped silicon melt; and
pulling a monocrystalline silicon ingot with the nitrogen-doped silicon melt by a Czochralski method.

7. The method according to claim 6, further comprising:
heating the quartz crucible to melt a silicon nitride and a polycrystalline silicon accommodated in the quartz crucible and to obtain the nitrogen-doped silicon melt.

8. The method according to claim 6, wherein conveying a carbon monoxide gas onto a liquid surface of the nitrogen-doped silicon melt comprises:
supplying the carbon monoxide gas; and
guiding the supplied carbon monoxide gas onto the liquid surface of the nitrogen-doped silicon melt.

9. The method according to claim 8, further comprising:
supplying an inert gas; and
guiding the supplied inert gas together with the carbon monoxide gas onto the liquid surface of the nitrogen-doped silicon melt.

10. The method according to claim 9, wherein the inert gas is an argon gas.
